(19) United States
(12) Patent Application Publication
(10) Pub. No.: US 2016/0064286 A1
(43) Pub. Date: Mar. 3, 2016

(54) INTEGRATED CIRCUITS AND METHODS FOR FABRICATING INTEGRATED CIRCUITS

(71) Applicant: GLOBALFOUNDRIES, Inc., Grand Cayman (KY)

(72) Inventors: Gabriela Dilliway, Dresden (DE); Bo Bai, Dresden (DE); Peter Javorka, Radeburg (DE); Dina H. Triyoso, Mechanicville, NY (US)

(21) Appl. No.: 14/476,031

(22) Filed: Sep. 3, 2014

(51) Int. Cl. H01L 21/8238; H01L 27/092

(52) U.S. Cl. CPC H01L 21/823814; H01L 21/823878; H01L 27/092

(57) ABSTRACT

Methods for fabricating integrated circuits and components thereof are provided. In accordance with an exemplary embodiment, a method for fabricating an integrated circuit is provided. The method includes providing a semiconductor substrate with a first gate structure and a second gate structure and a shallow trench isolation region outside of the first and second gate structures, depositing a mask on the first gate structure, and depositing a protection layer on the shallow trench isolation region to embed a STI protective cap.

### TECHNICAL FIELD

The present disclosure generally relates to integrated circuits and methods for fabricating integrated circuits.

### BACKGROUND

The majority of present day integrated circuits (ICs) are implemented by using a plurality of interconnected field effect transistors (FETs), also called metal oxide semiconductor field effect transistors (MOSFETs or MOS transistors). A MOS transistor includes a gate structure as a control electrode overlying a semiconductor substrate and spaced-apart source and drain regions in the substrate between which a current can flow. A gate insulator is deposited between the gate structure and the semiconductor substrate to electrically isolate the gate structure from the substrate. A control voltage applied to the gate structure controls the flow of current through a channel in the substrate underlying the gate structure between the source and drain regions.

A complementary metal oxide semiconductor (CMOS) device typically has both N- and P-type FETs. Such CMOS devices typically have shallow trench isolation (STI) regions formed with an insulator such as silicon oxide and positioned between N- and P-type FETs. Generally, it is desirable to maintain the STI oxide height during post-STI formation steps in order to reduce device variability and improve performance through providing better contacting for the STI-bounded devices. During some post-STI formation steps, such as embedded source-drain cavity formation, or post-implant photoresist removal, the STI height may be decreased substantially, resulting in a negative impact on the STI-bounded devices' performance and stability. Further, decreased STI height may lead to structural failure, such as due to punch-through when metal contacts land on sloped silicon structures.

Accordingly, it is desirable to provide integrated circuits and methods for fabricating integrated circuits that improve STI uniformity. Furthermore, other features and characteristics of the integrated circuits and methods for fabricating integrated circuits will become apparent from the subsequent detailed description and the appended claims, taken in conjunction with the accompanying drawings and this background.

### BRIEF SUMMARY

Integrated circuits and methods for fabricating integrated circuits are provided. In accordance with an exemplary embodiment, a method for fabricating an integrated circuit is provided. The method includes providing a semiconductor substrate with a first gate structure and a second gate structure and a shallow trench isolation region outside of the first and second gate structures, depositing a mask on the first gate structure, and depositing a protection layer on the shallow trench isolation region to embed a STI protective cap.

In accordance with another exemplary embodiment, a method is provided for fabricating an integrated circuit. The method includes providing a semiconductor substrate with a first gate structure and a second gate structure, forming a shallow trench isolation region proximate to one of the first and second gate structures, depositing a mask on one of the gate structures, depositing a protection layer on the shallow trench isolation region, encapsulating the first and second gate structures, depositing a mask on one of the first and second gate structures, forming cavities proximate to a base of the other electrode of the first and second gate structures, and embedding a source-drain epitaxial growth.

In accordance with a further exemplary embodiment, an integrated circuit is provided. The integrated circuit includes a first gate structure, a second gate structure, and a semiconductor substrate. The first gate structure and the second gate structure are formed overlying the semiconductor substrate. The integrated circuit further includes a shallow trench isolation region formed outside the first gate structure and the second gate structure, a first and a second spacer proximate to the second gate structure, and an STI protective cap embedded in the shallow trench isolation region. In one exemplary embodiment, the first spacer is adjacent to the shallow trench isolation region.

### BRIEF DESCRIPTION OF THE DRAWINGS

The various embodiments will hereinafter be described in conjunction with the following drawing figures, wherein like numerals denote like elements, and wherein:

FIGS. 1-8 illustrate, in cross section, a portion of an integrated circuit and method steps for fabricating an integrated circuit in accordance with an exemplary embodiment.

### DETAILED DESCRIPTION

The following detailed description is merely exemplary in nature and is not intended to limit the integrated circuits or methods for fabricating integrated circuits claimed herein. Furthermore, there is no intention to be bound by any theory presented in the preceding background or the following detailed description.

Integrated circuits that include a shallow trench isolation (STI) region and, in some embodiments, gate-last techniques for forming the integrated circuits are provided herein. In one exemplary embodiment, the STI region is covered with a low temperature highly conformal oxide protective layer. The protective layer has a lower etch rate than the STI region during subsequent processing steps. Thus, the STI region height can be preserved, resulting in reduced STI height variability, reduced device variability and improved performance through better contacting of the STI-bounded devices. The embodiments disclosed herein are suitable for any technology node, and some exemplary embodiments are suited for technology nodes of about 20-about 28 nm. In one exemplary embodiment, the integrated circuit includes multiple gate structures and the STI region separates one transistor from another.

As used herein, the term “semiconductor substrate” encompasses semiconductor materials conventionally used in the semiconductor industry. Semiconductor materials include monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. An exemplary semiconductor material is a silicon substrate. The silicon substrate may be a bulk silicon wafer or may be a thin layer of silicon on insulating layer (commonly known as silicon-on-insulator or SOI) that, in turn, is supported by a carrier wafer.

As used herein, the term “overlying” means “over” and “on,” wherein “on” means in direct physical contact and “over” means such that another layer may be interposed there between. Additionally, the terms “semiconductor device” and “integrated circuit” can be used interchangeably.

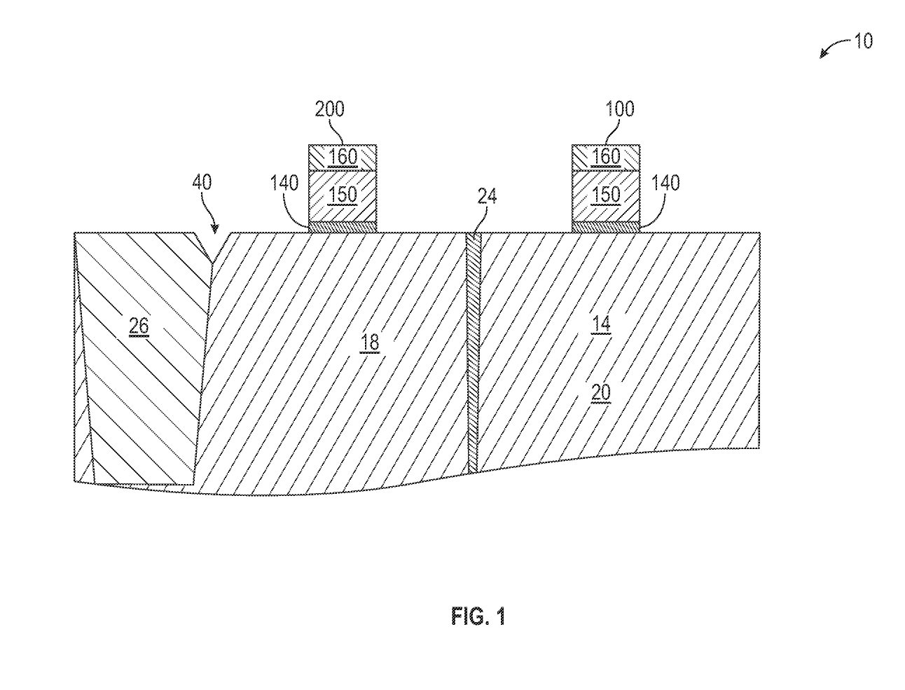

Referring to FIG. 1, a partially formed semiconductor device or integrated circuit (IC) 10 is provided having a first gate structure 100 overlying a well 14 having a dopant concentration, or a concentration of conductivity determining ions. The conductivity determining ions may be a P-type or N-type conductivity determining ions, depending upon whether a P-type metal-oxide-semiconductor (PMOS) transistor device or an N-type metal-oxide-semiconductor (NMOS) is to be formed. Although the term ‘MOS transistor device’ properly refers to a device having a metal gate electrode and an oxide gate insulator, that term is used herein to refer to any semiconductor device that includes a conductive gate electrode (whether metal or other conductive material). The well 14 contains opposite conductivity determining ions from the source region and drain region of transistors that are to be formed thereon. For example, when the source region and drain region for a transistor include P-type conductivity determining ions, the well 14 includes N-type conductivity determining ions, and vice versa. Typical N-type conductivity determining ions include, but are not limited to, phosphorus, arsenic, antimony, and combinations thereof. Typical P-type conductivity determining ions include, but are not limited to, boron, carbon, aluminum, gallium, indium, and combinations thereof. The integrated circuit 10 further includes a second gate structure 200 overlying a well 18 having a dopant concentration, or a concentration of conductivity determining ions. As with the well 14, the well 18 may be appropriately doped for use with a PMOS transistor or NMOS transistor. In an exemplary embodiment, the first gate structure 100 is intended to form an NMOS transistor and the second gate structure 200 is intended to form a PMOS transistor. The first gate structure 100 may be referred to as an NMOS gate structure and the second gate structure 200 may be referred to as a PMOS gate structure. As shown, the wells 14 and 18 are separated by a first shallow trench isolation (STI) region 24. A second shown trench isolation (STI) region 26 separates the well 18 of the second gate structure 200 from an adjacent structure (not shown), which in one exemplary embodiment is the well of another gate structure. STI regions 24 and 26 can be conventionally formed, with patterning and etching of the substrate to form recesses, followed by deposition of an insulator to fill the recesses. In an exemplary embodiment, the insulator is silicon oxide. It should be understood that a partially formed semiconductor device 10 can include at least one of the first gate structure 100 and the second gate structure 200. The first gate structure 100 and the second gate structure 200 are formed over a semiconductor substrate 20. As shown, another STI region or trench 40 is formed in the semiconductor substrate 20, particularly in at least a portion of the second STI region 26. In the illustration of FIG. 1, a single STI trench 40 is formed, although it is to be appreciated that numerous STI trenches 40 may be formed in the STI regions of the semiconductor device 10. In an exemplary embodiment, the STI trench 40 is formed using any suitable process and can be any suitable dimension depending on the application.

In accordance with an embodiment, the first gate structure 100 and the second gate structure 200 each include, discrete from one another, a gate insulation layer 140, an electrode material layer 150, and a hard mask layer 160. The gate insulation layer 140 can include but not limited to a high K dielectric material, i.e., a dielectric having a K value greater than about 3.8 (the dielectric constant “K” for silicon oxide), such as hafnium oxide, zirconium oxide or a combination thereof. In an exemplary embodiment, the gate insulation layer 140 is deposited by chemical vapor deposition (CVD). In other exemplary embodiments, polySiON gates are utilized.

The electrode material layer 150 can include one or more of layers of a dummy material overlying a capping layer, in turn overlying respective portions of the gate insulation layer 140. The dummy material may be any sacrificial material including, but not limited to a deposited silicon oxide, silicon nitride, silicon oxynitride, polycrystalline silicon, amorphous silicon, amorphous carbon (a-C), and a carbon-doped silica (SiCOH). It is to be appreciated that a particular type of material for the dummy material depends upon materials chosen for other structures that are present during selective removal of the dummy layer. In an exemplary embodiment, the dummy material includes undoped polycrystalline silicon. The capping layer within the electrode material layer 150 may include any conventional capping material employed in metal gates as a capping material over the respective gate insulation layer 140. Suitable materials for the metal capping layer include middle gap metal materials, which do not materially impact final work function of the gate structure. Examples of suitable middle gap materials include, but are not limited to, at least one of titanium nitride, titanium carbide, or silicon nitride. In one exemplary embodiment, titanium nitride is used. The gate insulation layer 140 may include a high K material. Examples of suitable high K dielectric materials include, but are not limited to, hafnium oxide, lanthanum oxide, zirconium oxide, tungsten oxide, iridium oxide, and aluminum oxide.

The term “dummy”, as referred to herein, means a structure or layer of which at least a portion is removed and replaced with other material during integrated circuit fabrication. In some embodiments and as shown in FIG. 1, numerous dummy gate electrode structures are patterned for later formation of gate structures through conventional gate-last formation techniques.

As shown, the hard mask layer 160 is formed over the electrode material layer 150. An exemplary hard mask layer 160 may be titanium nitride, titanium carbide, or silicon nitride, though other suitable materials may be used. In an exemplary embodiment, the hard mask layer 160 is deposited by chemical vapor deposition (CVD.) These layers may be formed through conventional blanket deposition techniques overlying the semiconductor substrate 20 followed by patterning.

In FIG. 1, the first gate structure 100 and the second gate structure 200 are patterned overlying semiconductor material of the semiconductor substrate 20. In particular, patterning of the first and second gate structures 100 and 200 may be conducted by first patterning the hard mask layer 160, followed by transferring the pattern in the hard mask layer 160 into underlying layers using appropriate etchants that are selective to the particular materials of layers 140 and 150 to form the first and second gate structures 100 and 200 of the semiconductor device 10.

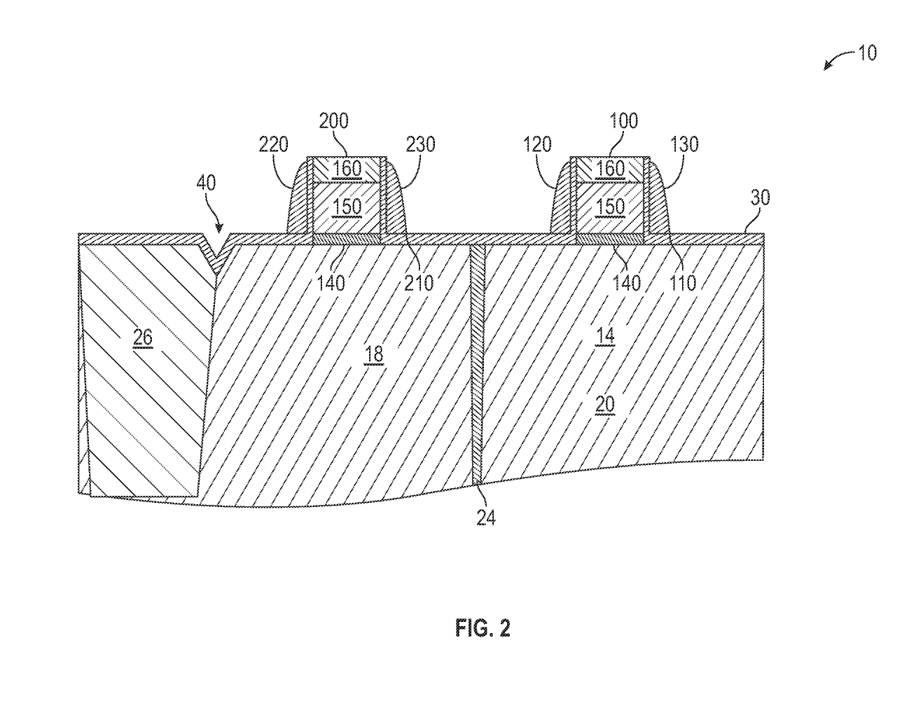

Referring to FIG. 2, spacers 120 and 130 are formed at respective sides of the first gate structure 100, and spacers 220 and 230 are formed at respective sides of the second gate structure 200. Prior to forming the spacers, an insulating layer 30 is deposited over the partially fabricated IC 10 including on the sides of the first and second gate structures 100 and 200, top of the hard mask layer 160, and partially filling the STI trench 40. The portions of the insulating layer 30 overlying the top of the hard mask layer 160 can be removed using any suitable process such as etching from the top of the hard mask layer 160. The spacers can be created by conformally depositing a dielectric material over the semiconductor substrate 20, where the dielectric material is an appropriate insulator, such as silicon nitride. The dielectric spacer material can be deposited in a known manner by, for example, atomic layer deposition (ALD), chemical vapor deposition (CVD), low pressure chemical vapor deposition (LPCVD), semi-atmospheric chemical vapor deposition (SACVD), or plasma enhanced chemical vapor deposition (PECVD). The layer of dielectric spacer material is deposited to a thickness so that, after anisotropic etching, the spacers 120, 130, 220 and 230 formed from the layer have a thickness that is appropriate for any subsequent process steps. After forming the spacers, the first gate structure 100 and the second gate structure 200 have, respectively, a base 110 and a base 210.

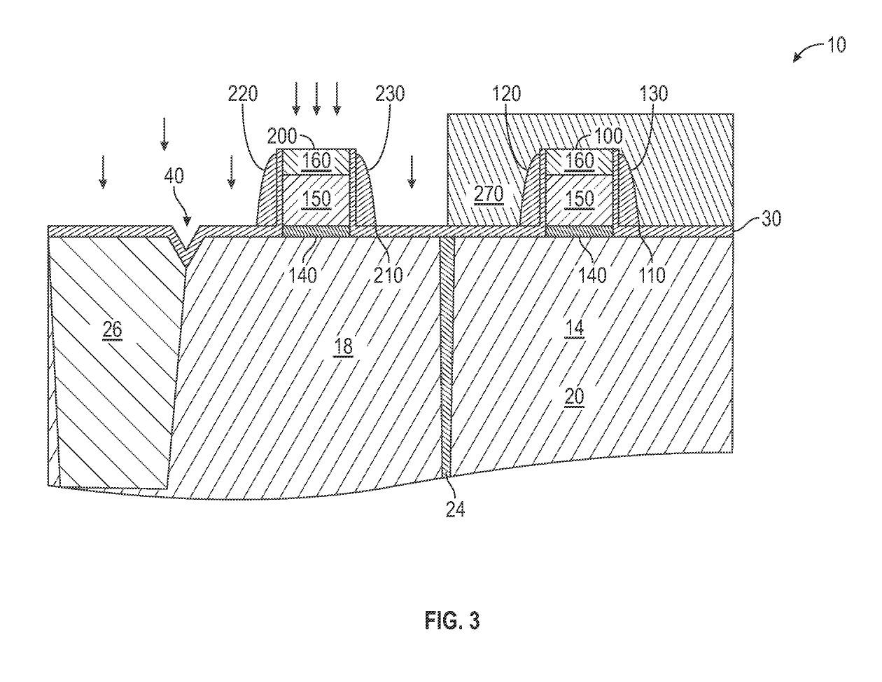

Referring to FIG. 3, the spacers 120 and 130, and 220 and 230 define source and drain regions and protect the gate structures 100 and 200 during subsequent high concentration dopant implantation. Prior to ion implantation, a mask 270 can be formed over the first gate structure 100. An exemplary mask 270 may be photoresist, although other suitable materials may be used. Dopants used for implantation about the base 210 of the second gate structure 200 can include boron, although any suitable dopant, as discussed above, may be used depending on the technology node and/or N- or P-type FET. An exemplary implantation process forms halo and/or extension implant regions. Afterwards, annealing can be conducted to stabilize and activate the implanted dopants.

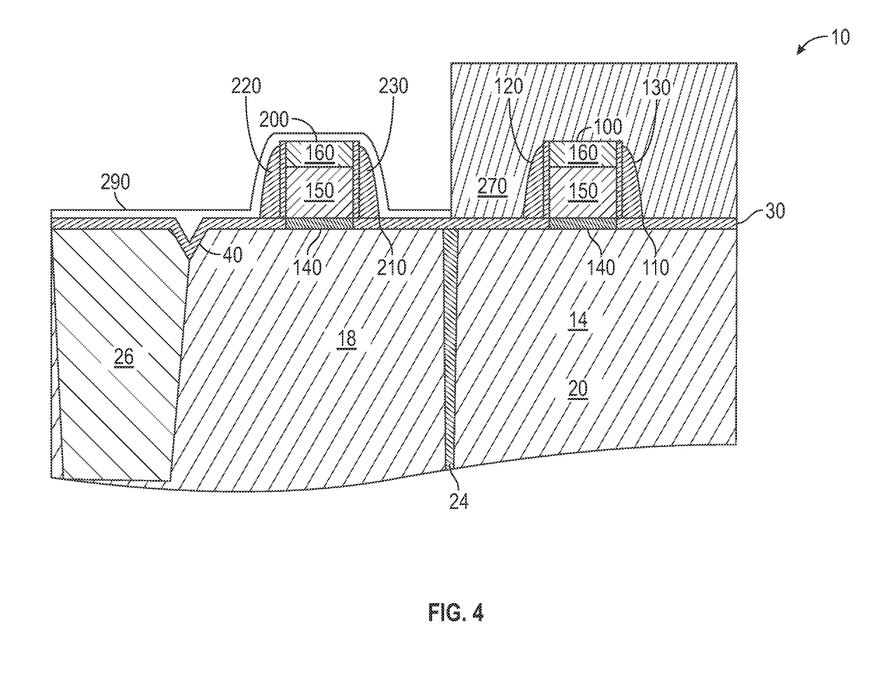

Referring to FIG. 4, a protection layer 290 is deposited overlying the semiconductor substrate 20 exposed by the second gate structure 200, and spacers 220 and 230. An exemplary deposition process fills the STI trench 40. The exemplary protection layer 290 can be of any suitable material, including the same material as the material forming the STI trench 40. In an exemplary embodiment, the protection layer 290 includes silicon oxide. The deposition process occurs at a temperature low enough to prevent dopant diffusion and degradation of the gate structures. An exemplary deposition temperature does not exceed about 400° C. For example, the deposition process may be performed from about 100° C. to about 400° C. An exemplary process is performed at a pressure of no more than about 1,400 Pascal. An exemplary protection layer 290 has a thickness suited to the technology application and device design. In one exemplary embodiment, the protection layer 290 is very thin and no more than about 10 Angstroms. Any suitable deposition method can be utilized, but atomic layer deposition (ALD) is used in an exemplary embodiment.

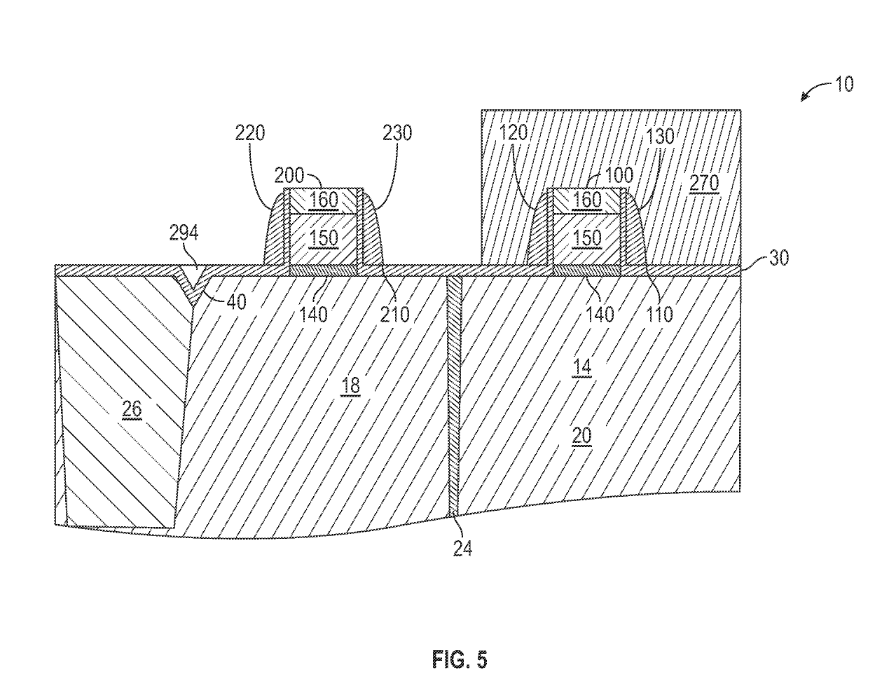

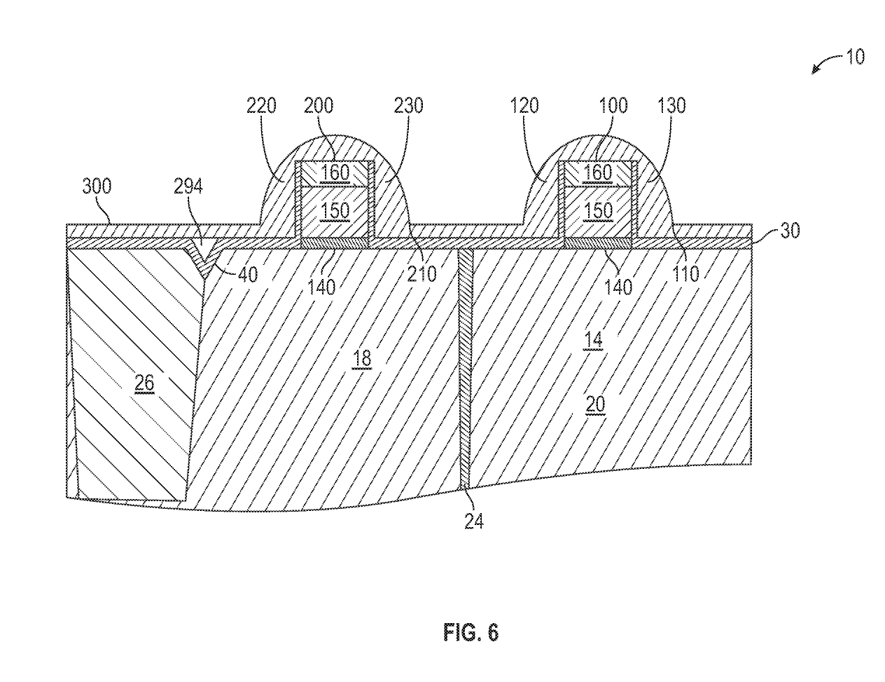

Referring to FIGS. 5-6, after the protection layer 290 is applied, a series of etching and depositing steps are undertaken. This series of steps leaves a thin layer, portion, or divot 294 filling the STI trench 40. These steps are conducted until the STI trench 40 is filled completely, leaving the portion 294, which is the accumulation of multiple deposits of the protection layer 290. A final etching step may be undertaken to remove any protection layer material 290 outside the STI trench 40. Next, the mask 270 is removed and an encapsulating layer or spacer 300, such as an interlayer dielectric material, is applied over the entire semiconductor substrate 20 using any suitable material or process, such as chemical vapor deposition or monolayer doping, applicable to the technology node.

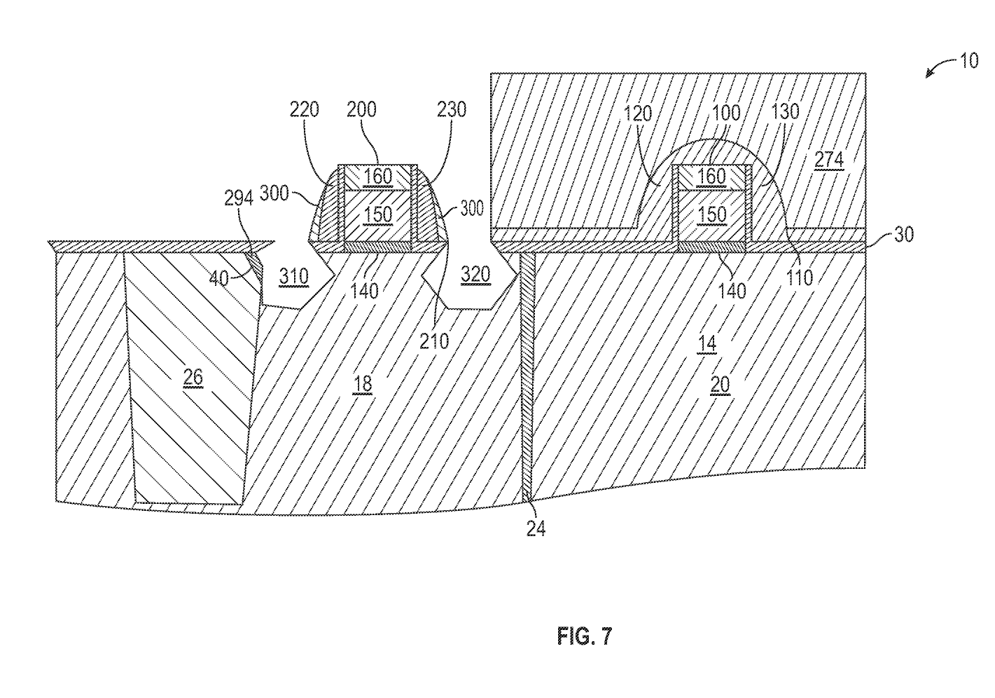

Referring to FIG. 7, another mask 274 using standard materials applicable for the technology node can be applied to the first gate structure 100. After the exemplary mask 274 is formed, a portion of the encapsulating layer 300 may be removed from the semiconductor substrate 20 exposed by the mask 274 and from the top of the second gate structure 200. Portions of the encapsulating layer 300 may remain on the sides of the second gate structure 200. As shown, a first source-drain cavity 310 and a second source-drain cavity 320 are formed in the semiconductor substrate 20 proximate to the STI protective cap 294 and at the base of the second gate structure 200. In this exemplary embodiment, the STI trench 40 and the STI protective cap 294 define opposing edges of the first source-drain cavity 310. The second gate structure 200 including the encapsulating layer 300 and the mask 274 define opposing edges of the second source-drain cavity 320. In other exemplary embodiments, the second source-drain cavity 320 is defined by the gate 200 including the spacers 220 and 230 and the encapsulating layer 300 on one edge and, instead of the mask 274, be defined by a gate having spacers and an encapsulating layer or another STI region 26 along with an additional STI trench 40 and protective cap 294. The first source-drain cavity 310 and second source-drain cavity 320 can be etched with any suitable process and/or reagent, such as hydrogen chloride or tetramethyl ammonium hydroxide, for forming the cavities 310 and 320. Alternatively, the cavities 310 and 320 can be formed by reactive ion etch. Any suitable shape of cavities can be formed, independently, and such cavities may be U-shaped or sigma shaped. In this exemplary embodiment the cavities 310 and 320 are sigma shaped. These cavities 310 and 320 are formed at the base 210 proximate to the portions of the encapsulating layer on the second gate structure 200 in order to embed the source and drain regions of the semiconductor device 10. During the etch process, the protective cap 294 prevents etching of the STI region 26 and maintains the height of the STI region 26. After etching, the protective cap 294 can include remnants of the protection layer 290 and/or the insulating layer 30. As shown, after the formation of cavities 310 and 320, the STI region 26 is still protected with the STI protective cap 294 positioned in the STI trench 40 and overlying the STI region 26.

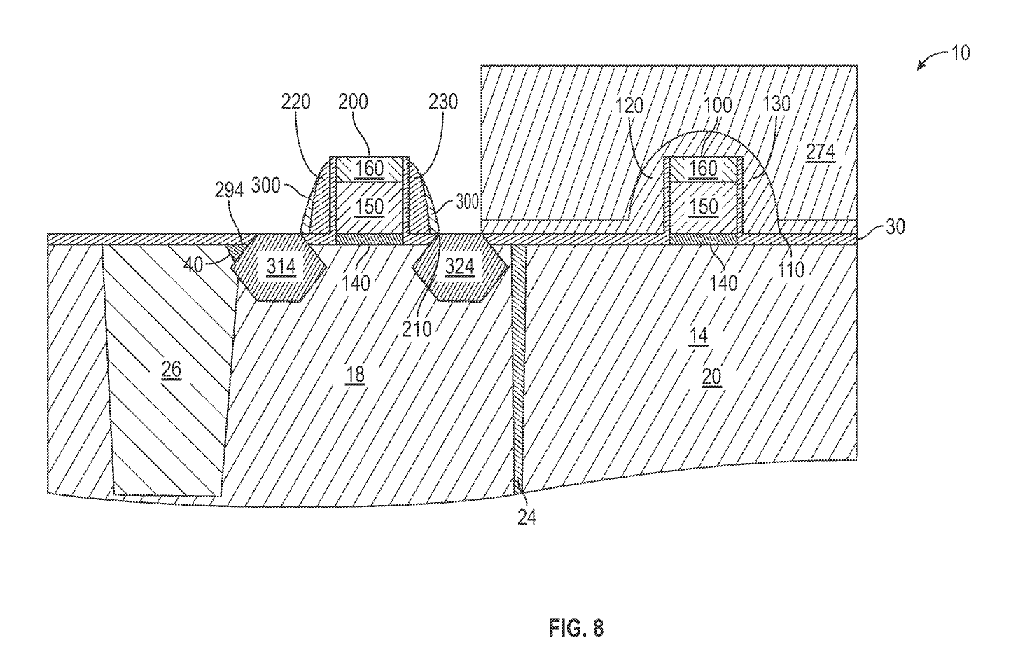

Referring to FIG. 8, a first growth 314 and a second growth 324 is embedded in respective cavities 310 and 320. Specifically, after precleaning, an epitaxial material is deposited by a low-pressure chemical vapor deposition process. The deposition process epitaxially grows layers to form the source/drain areas around the second gate structure 200. In an exemplary embodiment, this process allows silicon-germanium epitaxial layers to fill the cavities 310 and 320 with growths 314 and 324. The epitaxial growths 314 and 324 can provide an increased strain to the channel, and thus enhance carrier mobility or transistor drive current. Subsequent processes can be performed to finalize semiconductor fabrication, including subsequent etching steps, e.g., removal of the mask 274, replacement gate processing, contact formation and other back-end-of-line (BEOL) processing.

The embodiments disclosed herein can be utilized for various sizes and configurations, such as a distance between the source side and the drain side of no more than about 28, about 20, about 14, or about 10 nm. Configurations utilized can include fin-based, multi-gate transistor, bulk, or silicon-on-insulator. The embodiments herein can be used for low power and high performance products.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the application in any way. Rather, the foregoing detailed description will provide those skilled in the art with a convenient road map for implementing one or more exemplary embodiments. It being understood that various changes may be made in the function and arrangement of elements described in an exemplary embodiment without departing from the scope set forth in the appended claims.

What is claimed is:

1. A method for fabricating an integrated circuit, comprising:
providing a semiconductor substrate with a first gate structure and a second gate structure and a shallow trench isolation region outside of the first and second gate structures;
depositing a mask on the first gate structure; and
depositing a protection layer on the shallow trench isolation region to embed a STI protective cap.

2. The method according to claim 1, further comprising etching a source-drain cavity in the semiconductor substrate with an etchant, wherein the STI protective cap blocks contact between the etchant and the shallow trench isolation region.

3. The method according to claim 1, further comprising etching a trench into the shallow trench isolation region, wherein depositing a protection layer comprises at least partially filling the trench with the protection layer to form the STI protective cap.

4. The method according to claim 1, wherein depositing the protection layer on the shallow trench isolation region comprises depositing the protection layer by atomic layer deposition.

5. The method according to claim 3, wherein the first gate structure forms an N-channel metal oxide semiconductor gate structure and the second gate structure forms a P-channel metal oxide semiconductor gate structure.

6. The method according to claim 1, wherein depositing the protection layer comprises depositing the protection layer at a temperature of no more than about 400° C.

7. The method according to claim 1, wherein depositing the protection layer comprises depositing the protection layer at a temperature from about 100° C. to about 400° C.

8. The method according to claim 7, wherein depositing the protection layer comprises depositing the protection layer at a pressure of no more than about 1,400 Pascal.

9. The method according to claim 1, wherein the method for fabricating an integrated circuit further comprises providing an integrated circuit comprising multiple gate structures and the shallow trench isolation region separates one transistor from another.

10. The method according to claim 1, wherein depositing the protection layer comprises depositing silicon oxide.

11. The method according to claim 1, wherein depositing the protection layer comprises depositing the protection layer on the shallow trench isolation region and outside of the shallow trench isolation region, and wherein the method further comprises removing the protection layer outside of the shallow trench isolation region.

12. The method according to claim 11, further comprising forming a source-drain cavity in the semiconductor substrate, wherein the cavity is proximate to the protection layer in a shallow trench isolation trench.

13. A method for fabricating an integrated circuit, comprising:
providing a semiconductor substrate with a first gate structure and a second gate structure;
forming a shallow trench isolation region outside of the first and second gate structures;
depositing a mask on the second gate structure;
depositing a protection layer on the shallow trench isolation region;
encapsulating the first and second gate structures;
depositing a mask on one of the first and second gate structures;
forming cavities proximate to a base of the other structure of the first and second gate structures; and
embedding a source-drain epitaxial growth.

14. The method according to claim 13, wherein depositing the protection layer on the shallow trench isolation region comprises depositing the protection layer by atomic layer deposition.

15. The method according to claim 13, wherein the integrated circuit further comprises an N-channel metal oxide semiconductor and a P-channel metal oxide semiconductor.

16. The method according to claim 13, wherein depositing the protection layer comprises depositing the protection layer at a temperature of no more than about 400° C.

17. The method according to claim 13, wherein depositing the protection layer comprises depositing the protection layer at a temperature from about 100° C. to about 400° C.

18. The method according to claim 17, wherein depositing the protection layer comprises depositing the protection layer at a pressure of no more than about 1,400 Pascal.

19. An integrated circuit, comprising:
a first gate structure;
a second gate structure;
a semiconductor substrate wherein the first gate structure and the second gate structure are formed overlying the semiconductor substrate;
a shallow trench isolation region formed outside the first gate structure and the second gate structure;
a first and a second spacer proximate to the second gate structure wherein the first spacer is adjacent to the shallow trench isolation region; and
an STI protective cap embedded in the shallow trench isolation region.

20. The integrated circuit according to claim 19, wherein the STI protective cap comprises silicon oxide.
